(19) United States
(12) Patent Application Publication
(10) Pub. No.: US 2004/0251546 A1
(43) Pub. Date: Dec. 16, 2004

(54) Package and method for bonding between gold lead and gold bump

(76) Inventors: Si-Hoon Lee, Cheonan-city (KR); Sa-Yoon Kang, Seoul (KR); Dong-Han Kim, Osan-city (KR); Yong-Hwan Kwon, Suwon-city (KR); Chung-Sun Lee, Suwon-city (KR)

Correspondence Address: HARNESS, DICKEY & PIERCE, P.L.C., P.O. BOX 8910, RESTON, VA, 20195, US

(21) Appl. No.: 10/778,126

(22) Filed: Feb. 17, 2004

(30) Foreign Application Priority Data
Jun. 12, 2003 (JP) 2003-37861

(51) Int. Cl. B23K 31/02; H01L 23/34

(52) U.S. Cl. 257/738; 228/180.22

(57) ABSTRACT

A chip package including at least one interconnection lead, composed of at least one first metal, at least one bump, a surface of which is plated with at least one second metal with a melting point lower than the first metal, and a eutectic alloy, composed of the at least one first metal and the at least one second metal, that at least electrically connects the interconnection lead and the bump and a method of manufacturing a chip package.

### BACKGROUND OF THE INVENTION

This application claims the priority of Korean Patent Application No. 2003-37861, filed on Jun. 12, 2003, in the Korean Intellectual Property Office, the disclosure of which is incorporated herein in its entirety by reference.

1. Field of the Invention

The present invention relate to a semiconductor package and method, and more particularly, to a package and method for bonding a gold or gold-plated lead and a gold bump.

2. Description of the Related Art

A liquid crystal display drive integrated circuit (LDI) package used to drive a display device, such as a liquid crystal display (LCD) may be formed by tape automated bonding (TAB) in which an integrated circuit chip or a semiconductor chip is mounted on a tape made of, for example, an organic material. This type of package may be used in an integrated circuit chip or a semiconductor chip package, a mobile phone, display device of a video game, etc. A TAB-type package may use the structure of a tape carrier package (TCP) or a chip on film (COF) package. A TCP is commonly used for obtaining thin products.

A TAB-type package provides an interconnection lead on a tape (or a film), and a bump on a semiconductor chip. Obtaining a TAB, TCP or COF type package requires connecting the semiconductor chip and the tape by bonding an interconnection lead and a bump.

In the conventional art, a tin layer on the interconnection lead causes problems at an outer lead bonding (OLB) part that is exposed outside of a chip package and contacts or is inserted into a socket of another device. These problems may include poor connectivity and/or tin diffusion.

For instance, tin can induce a commonly known “whisker phenomenon” that generates an undesired short between leads by having “whiskers” of tin protruding between the leads. After the TAB, TCP, or COF type package is formed, the exposed OLB is electrically connected to an external device, generally through anisotropic conductive film (ACF) bonding.

Furthermore, the tin plated interconnection lead causes several problems in an inner lead bonding (ILB) part, for example, a lead neck may break due to tin diffusion.

Therefore, in order to improve thermal or external reliability at the contact between the interconnection lead and the bump and the thermal reliability of a connection between the interconnection lead and another device, a gold or gold-plated interconnection lead may be connected to a gold bump. Further, the exposed surface of the OLB bonding part that is protruding outside of the chip package and contacts or is inserted into the socket of another device is made of gold or gold-plated.

In this respect, many efforts have been made to connect a gold bump and a gold or gold-plated interconnection lead on a surface thereof. For example, U.S. Pat. No. 6,518,649 to Tomokiho Iwane et al. entitled “Tape Carrier Type Semiconductor Device with Gold/Gold Bonding of Leads to Bumps,” filed on Feb. 11, 2003, discloses an approach to gold-gold bonding through thermal compression bonding.

Thermal compression bonding has many disadvantages including a relatively weak connection intensity. In addition, lead problems may occur in products having unequal heights between the bump and the interconnection lead since the interconnection lead has to penetrate into the bump in this type of bonding.

### SUMMARY OF THE INVENTION

At least one exemplary embodiment of the present invention provides a chip package including at least one interconnection lead, composed of at least one first metal, at least one bump, a surface of which is plated with at least one second metal with a melting point lower than the first metal, and a eutectic alloy, composed of the at least one first metal and the at least one second metal, that at least electrically connects the interconnection lead and the bump and a method of manufacturing a chip package.

At least one exemplary embodiment of the present invention provides a chip package including at least one interconnection lead composed of at least one first metal on an exposed surface, the interconnection lead extending from an outer lead bonding part to an inner lead bonding part on a tape carrier, a chip having at least one bump plated with at least one second metal with a melting point lower than the first metal, the bump opposing the interconnection lead and the inner lead bonding part, and a eutectic alloy, composed of the at least one first metal and the at least one second metal, that at least electrically connects the interconnection lead and the bump.

At least one exemplary embodiment of the present invention provides a method of manufacturing a chip package including providing at least one interconnection lead, at least partially composed of gold, plating at least one metal layer on an upper surface of at least one bump, and forming a eutectic alloy, composed of gold and the at least one metal layer, that at least electrically connects the interconnection lead and the bump.

### BRIEF DESCRIPTION OF THE DRAWINGS

The above and other features and advantages of the present invention will become more apparent by describing in detail exemplary embodiments thereof with reference to the attached drawings in which:

FIG. 1 is a plan view schematically illustrating a chip package according to an exemplary embodiment of the present invention;

FIG. 2 is a cross-sectional view schematically illustrating a chip package according to an exemplary embodiment of the present invention; and

FIGS. 3 through 8 are cross-sectional views schematically illustrating a manufacturing method of a chip package according to an exemplary embodiment of the present invention.

### DETAILED DESCRIPTION OF EXEMPLARY EMBODIMENTS OF THE INVENTION

The exemplary embodiments of the present invention now will be described more fully with reference to the attached drawings, in which exemplary embodiments of the invention are shown.

Exemplary embodiments of this invention may, however, be embodied in many different forms and should not be construed as limited to the embodiments set forth herein.

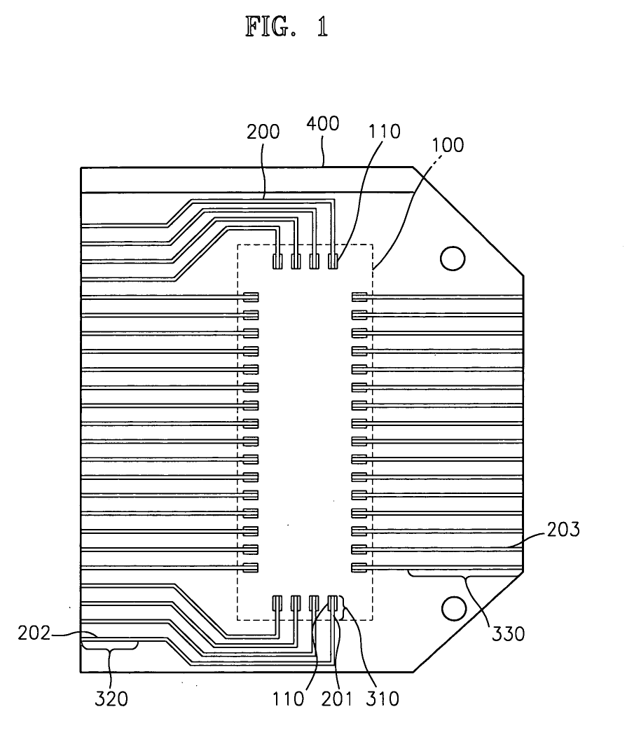

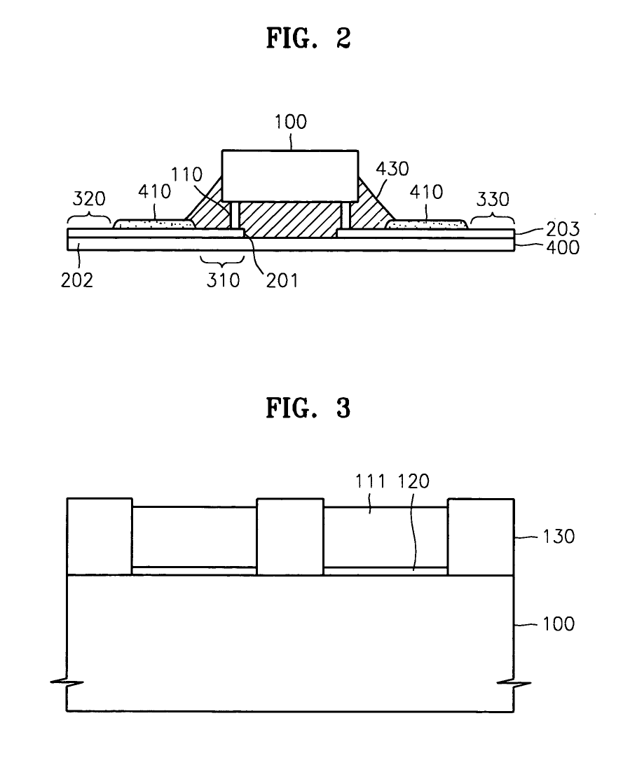

Referring to FIGS. 1 and 2, a chip package has a tape (or a tape carrier) 400 mounted on a semiconductor chip or an integrated circuit chip 100. A plurality of bumps 110 are provided on the integrated circuit chip 100 and a plurality of parallel interconnection leads 200 are provided between the integrated circuit chip 100 and in the tape 400.

Each of the plurality of parallel interconnection leads 200 includes an inner lead part 201 and an outer lead part 202, 203. The inner lead parts 201 of the plurality of parallel interconnection leads 200 are connected to an inner boding part 310 and the outer lead parts 202 and 203 of the interconnection leads 200 are connected at outer lead bonding parts 320 and 330 and may be exposed.

The package of FIG. 1 may be a LCD driver integrated circuit (LDI) package used in a liquid crystal display or a display driver IC (DDI) package used in a display device such as a plasma display panel driver IC (PDI) for a plasma display panel (PDP) as non-limiting examples. In the LDI package example, the outer lead 202 may be connected to an electrode of a liquid crystal panel through an anisotropic conductive film (ACF) and the outer lead 203 may be connected to an electrode of a printing circuit board where image data is transmitted.

The tape 400 may be made of an organic material such as polyimide as one non-limiting example. Each interconnection lead 200 patterned on a surface of the tape 400 may be made of gold, gold-plated copper wire, or other conductor. Bumps 110 may have a tin layer plated on a surface thereof. Tin has a relatively low melting point, and thus, a similar low melting point metal, such as, lead may be optionally or additionally plated on the surface of the bumps.

The bumps 110 and inner lead 201 may be connected via an eutectic alloy, described in more detail below. The connection between the bumps 110 and the inner leads 201 may be sealed with an insulated material 430, such as an underfill resin or a non-conductive paste (NCP), as non-limiting examples. Also, the interconnection leads 200 between the inner lead 201 and the outer leads 202 and 203 may be protected by a solder resist 410 or other similarly protective materials. The outer leads 202 and 203 of the package may be exposed as illustrated in FIG. 2.

The interconnection leads 200 and the bumps 110 may be prepared first in order to organize the package. Alternatively, the bumps 110 and leads 200 may be last if different organization of the package is required.

FIG. 3 illustrates a bump 110 in more detail. The bump 110 may be formed by patterning a gold layer 111, by lining up an electrode 120 of the semiconductor chip 100. A film 130 may be used to pattern the gold layer 111 with the bumps 110. Alternatively, another material may be used to pattern the gold layer 111 with the bumps 110.

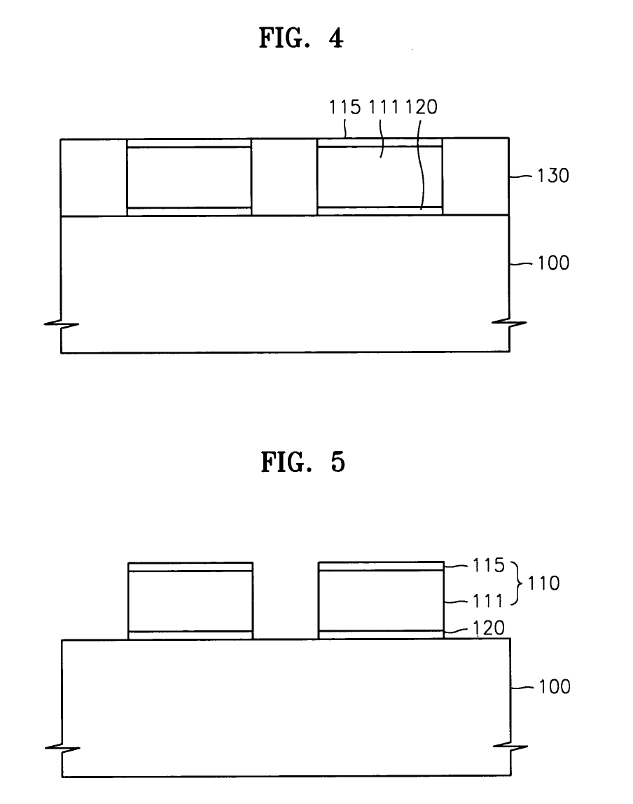

Referring to FIG. 4, a tin layer 115 may be selectively plated on the gold layer 111. The tin layer 115 may be formed to have a thickness ranging from 0.1 to 10 μm in order to provide enough tin for connecting to the interconnection lead 110 via a eutectic alloy. This range may vary, however, depending on the amount of tin, lead or other low melting point metal that is required to form the eutectic alloy. The plated tin layer 115 also forms an alloy layer with the gold layer 111. This alloy may be eutectic, but need not be. Nonetheless, a pure or substantially pure tin layer may remain on an upper surface of the tin layer 115. A remaining pure or substantially pure tin layer reacts with the gold or the gold plating of the interconnection leads 200 to form a eutectic alloy.

The tin layer 115 may be formed to have a thickness ranging from 0.1 to 10 μm in order to provide enough tin for connecting to the interconnection lead 110 via a eutectic alloy. This range may vary, however, depending on the amount of tin required to form the eutectic alloy.

Tin has a relatively low melting point when compared to gold, and thus, another low melting point metal, such as lead, may be optionally or additionally plated on the surface of the bumps 110.

Referring to FIG. 5, instead of using the pattern 130 of FIG. 4, the gold layer 111 and the tin layer 115 may be selectively place on an upper surface of the integrated circuit chip 100.

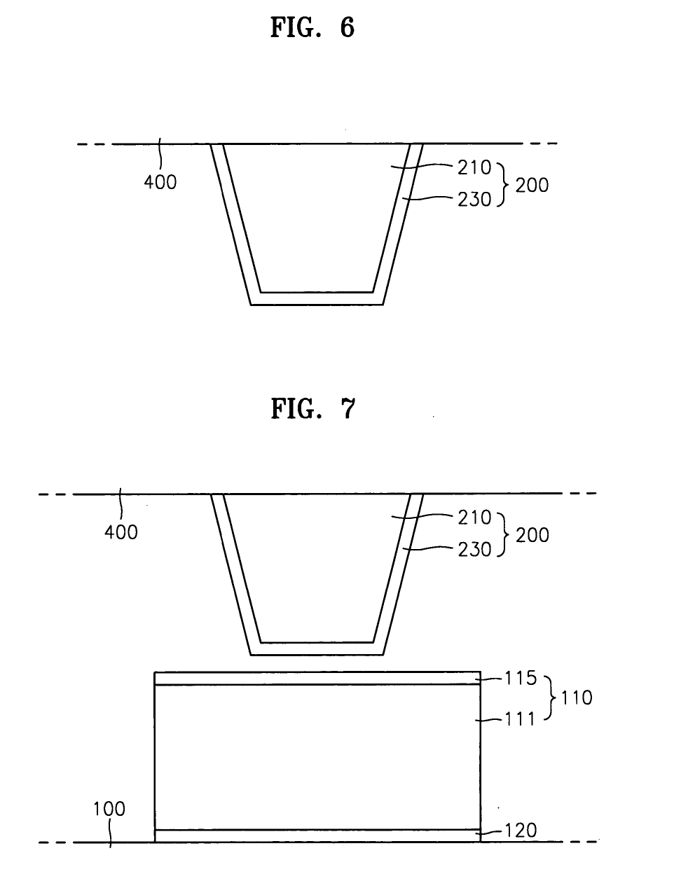

As set forth above, the interconnection leads 200 may be gold or have at least one gold layer on a surface thereof. Referring to FIG. 6, the interconnection lead 200 may be metal-patterned, for example, from a copper layer 210 on the tape 400. A gold layer 230 may be plated on the surface of the copper layer 210, thereby forming the interconnection leads 200 covered by the gold layer 230. Thus, the outer leads 202 and 203, and the inner lead 201 may be all gold-plated on a surface thereof.

Referring to FIG. 7, the interconnection leads 200 and the bumps 110 may come in contact or be positioned sufficiently close together to form the eutectic alloy. In an exemplary embodiment, the connecting process may be conducted for about two seconds at a high temperature, for example, 500° C. However, this process may vary from 0.1 second to 5 seconds at temperatures ranging from 400° C.-600° C. A raised pressure may be applied to the bumps 110. However, the above conditions may be varied as necessary to form the desired eutectic alloy to connect the interconnection leads 200 and the bumps 110.

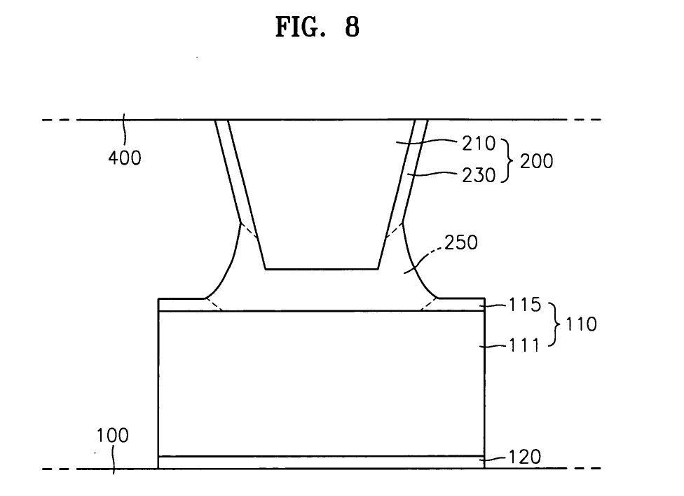

Referring to FIG. 8, a tin-gold eutectic alloy 250 is illustrated between the interconnection leads 200 and the bumps 110. In exemplary embodiments, the eutectic alloy 250 may be AuSn₄ or may be an Au-rich alloy. These exemplary alloys are known to have a ductile characteristics.

The eutectic alloy 250 provides a high intensity connection which provides stability in the connection between the interconnection leads 200 and the bumps 100.

In an exemplary embodiment, an inner lead of each interconnection lead 200 may be connected to a bonding part 310 by an inner lead bonding (ILB) which is made up of a eutectic alloy.

Moreover, even when plating the interconnection leads 200 with the gold layer 230, a connection via the eutectic alloy may be embodied by introducing the tin layer plated bumps 110 on the gold layer 111. Accordingly, thermal reliability and stability of the interconnection leads 200, and concurrently connection stability and reliability of the bond between the interconnection leads 200 and the bumps 110 may be realized.

Furthermore, the use of the gold plated interconnection leads may improve the thermal reliability on an exposed part of the OLB part in the package. Still further, a stiffener may be attached to the backside of the OLB portion of the chip and inserted into a slot, to provide a more reliable contact.

As described above, a connection between a gold or gold plated interconnection lead 200 and a bump 110 may be embodied as a tin-gold eutectic alloy by plating the upper surface of the bump with the tin layer in at least one exemplary embodiment of the present invention. This can strengthen a connection intensity between the interconnection lead and the bump.

At least one of the exemplary embodiments of the invention provide a chip package structure employing a eutectic alloy of a tin layer plated gold bump and an interconnection lead. More specifically, the gold bump plated with a tin layer on an integrated circuit device or on a surface thereof, and the interconnection lead is made of gold or is plated with a gold layer on a surface thereof in a tape or a tape carrier. Both the gold bump and the interconnection lead are placed in the chip package.

The eutectic alloy bonding of gold and tin provides a stronger and more intense bond between the gold bump and the interconnection lead. In at least one exemplary embodiment of the present invention, the interconnection lead is gold plated on the surface thereof in an outer lead bonding (OLB) part. This gold plating reduces or prevents the tin whisker phenomenon in the OLB part, and thus improves thermal stability and/or reliability, including the external reliability of the interconnection lead.

While the exemplary embodiments of the present invention have been particularly shown and described, it will be understood by those of ordinary skill in the art that various changes in form and details may be made therein without departing from the spirit and scope of the present invention as defined by the following claims.

What is claimed is:

1. A chip package comprising:
at least one interconnection lead, composed of at least one first metal;
at least one bump, a surface of which is plated with at least one second metal with a melting point lower than the first metal; and
a eutectic alloy, composed of the at least one first metal and the at least one second metal, that at least electrically connects the interconnection lead and the bump.

2. The chip package of claim 1, wherein the at least one first metal is a gold layer.

3. The chip package of claim 1, wherein the bump includes a gold layer.

4. The chip package of claim 1, wherein the at least one second metal is a tin layer.

5. The chip package of claim 1, wherein the at least one second metal is a lead layer.

6. The chip package of claim 1, wherein the interconnection lead is a gold plated copper wire.

7. The chip package of claim 1, wherein the at least one first metal is gold and the at least one second metal is tin.

8. The chip package of claim 1, wherein the at least one first metal is gold and the at least one second metal is lead.

9. A chip package comprising:
at least one interconnection lead composed of at least one first metal on an exposed surface, the interconnection lead extending from an outer lead bonding part to an inner lead bonding part on a tape carrier;
a chip having at least one bump plated with at least one second metal with a melting point lower than the first metal, the bump opposing the interconnection lead and the inner lead bonding part; and
a eutectic alloy, composed of the at least one first metal and the at least one second metal, that at least electrically connects the interconnection lead and the bump.

10. The chip package of claim 9, wherein the at least one first metal is a gold layer.

11. The chip package of claim 9, wherein the bump includes a gold layer.

12. The chip package of claim 9, wherein the at least one first metal is gold and the at least one second metal is tin.

13. The chip package of claim 9, wherein the at least one first metal is gold and the at least one second metal is lead.

14. The chip package of claim 9, further comprising an insulation material filled between the chip and the tape carrier to seal the bonding.

15. The chip package of claim 9, wherein the at least one interconnection lead is a gold plated copper wire.

16. A method of manufacturing a chip package comprising:
providing at least one interconnection lead, at least partially composed of gold;
plating at least one metal layer on an upper surface of at least one bump; and
forming a eutectic alloy, composed of gold and the at least one metal layer, that at least electrically connects the interconnection lead and the bump.

17. The method of manufacturing according to claim 16, wherein forming the eutectic alloy includes applying a high temperature for about two seconds.

18. The method of manufacturing according to claim 16, wherein forming the eutectic alloy includes raising the temperature to about 500° C.
